(19) United States
(12) Patent Application Publication
(10) Pub. No.: US 2025/0248316 A1
(43) Pub. Date: Jul. 31, 2025

(54) MAGNETIC DOMAIN WALL MOTION ELEMENT AND MAGNETIC ARRAY

(71) Applicant: TDK CORPORATION, Tokyo (JP)

(72) Inventor: Tatsuo SHIBATA, Tokyo (JP)

(73) Assignee: TDK CORPORATION, Tokyo (JP)

(21) Appl. No.: 18/425,376

(22) Filed: Jan. 29, 2024

(51) Int. Cl. H10N 50/80; H10B 61/00; H10N 50/10

(52) U.S. Cl. CPC H10N 50/80; H10B 61/22; H10N 50/10

(57) ABSTRACT

This magnetic domain wall motion element includes a first ferromagnetic layer, a first magnetization fixed portion, and a second magnetization fixed portion. The first magnetization fixed portion includes a first magnetization fixed layer, a first nonmagnetic layer, and a second magnetization fixed layer having a first diffusion prevention structure. The second magnetization fixed portion includes a third magnetization fixed layer, a second nonmagnetic layer, and a fourth magnetization fixed layer. The fourth magnetization fixed layer has a second diffusion prevention structure and a first region. The first region is located at a position further away from the second nonmagnetic layer than the second diffusion prevention structure. The first region contains a ferromagnetic element and a nonmagnetic element.

### BACKGROUND OF THE INVENTION

### Field of the Invention

The present disclosure relates to a magnetic domain wall motion element and a magnetic array.

### Description of Related Art

A magnetoresistive element that utilizes a change in resistance value (a change in magnetoresistance) based on a change in relative angle of a magnetization between two ferromagnetic layers is known. For example, a magnetic domain wall motion type magnetoresistive element (hereinafter referred to as a magnetic domain wall motion element) described in Patent Document 1 is an example of a magnetoresistive element. In the magnetic domain wall motion element, a resistance value in a stacking direction changes depending on a position of a domain wall, and data can be recorded in a multi-level or analog manner. The magnetic domain wall motion element has high linearity and symmetry in resistance change and excellent rewriting resistance, and is capable of high-speed operation.

Patent Document 1 describes that magnetization fixed portions that limit a movement range of the domain wall are provided at both ends of a magnetic recording layer. Magnetization orientation directions of the two magnetization fixed portions are different from each other.

### PATENT DOCUMENTS

[Patent Document 1] PCT International Publication No. WO 2020/230877

### SUMMARY OF THE INVENTION

It is not easy to orient the magnetization orientation directions of the two magnetization fixed portions in different directions.

The present disclosure has been made in view of the above problems, and an object of the present disclosure is to provide a magnetic domain wall motion element and a magnetic array having high reliability.

A magnetic domain wall motion element according to a first aspect includes: a first ferromagnetic layer having a domain wall therein; a first magnetization fixed portion connected to the first ferromagnetic layer; and a second magnetization fixed portion connected to the first ferromagnetic layer at a position separated from the first magnetization fixed portion. The first magnetization fixed portion includes a first magnetization fixed layer, a first nonmagnetic layer, and a second magnetization fixed layer. The first magnetization fixed layer and the second magnetization fixed layer are antiferromagnetically coupled to each other with the first nonmagnetic layer interposed therebetween. The first magnetization fixed layer is in contact with the first ferromagnetic layer. The first nonmagnetic layer is located between the first magnetization fixed layer and the second magnetization fixed layer in a stacking direction. The second magnetization fixed layer has a first diffusion prevention structure. The second magnetization fixed portion includes a third magnetization fixed layer, a second nonmagnetic layer, and a fourth magnetization fixed layer. The third magnetization fixed layer and the fourth magnetization fixed layer are antiferromagnetically coupled to each other with the second nonmagnetic layer interposed therebetween. The third magnetization fixed layer is in contact with the first ferromagnetic layer. The second nonmagnetic layer is located between the third magnetization fixed layer and the fourth magnetization fixed layer in the stacking direction. The fourth magnetization fixed layer has a second diffusion prevention structure and a first region. The first region is located at a position further away from the second nonmagnetic layer than the second diffusion prevention structure. The first region contains a ferromagnetic element and a nonmagnetic element.

### BRIEF DESCRIPTION OF THE DRAWINGS

FIG. 1 is a block diagram of a magnetic array according to a first embodiment.

FIG. 2 is a circuit diagram of an integrated region of the magnetic array according to the first embodiment.

FIG. 3 is a cross-sectional view of the vicinity of a magnetic domain wall motion element of the magnetic array according to the first embodiment.

FIG. 4 is a cross-sectional view of the magnetic domain wall motion element according to the first embodiment.

FIG. 5 is a plan view of the magnetic domain wall motion element according to the first embodiment.

FIG. 6 is a cross-sectional view of a first magnetization fixed portion according to the first embodiment.

FIG. 7 is a cross-sectional view of a second magnetization fixed portion according to the first embodiment.

FIG. 8 is a conceptual diagram of a neural network.

FIG. 9 is a block diagram showing a system including a neuromorphic device according to the first embodiment.

### DETAILED DESCRIPTION OF THE INVENTION

Hereinafter, the present embodiment will be described in detail with appropriate reference to the drawings. In the drawings used in the following description, feature portions may be enlarged for convenience to make the features of the present embodiment easy to understand, and dimensional ratios of each constituent element and the like may be different from the actual ones. Materials, dimensions, and the like exemplified in the following description are examples, and the present embodiment is not limited thereto and can be appropriately modified and carried out within the scope in which the effects of the present embodiment are exhibited.

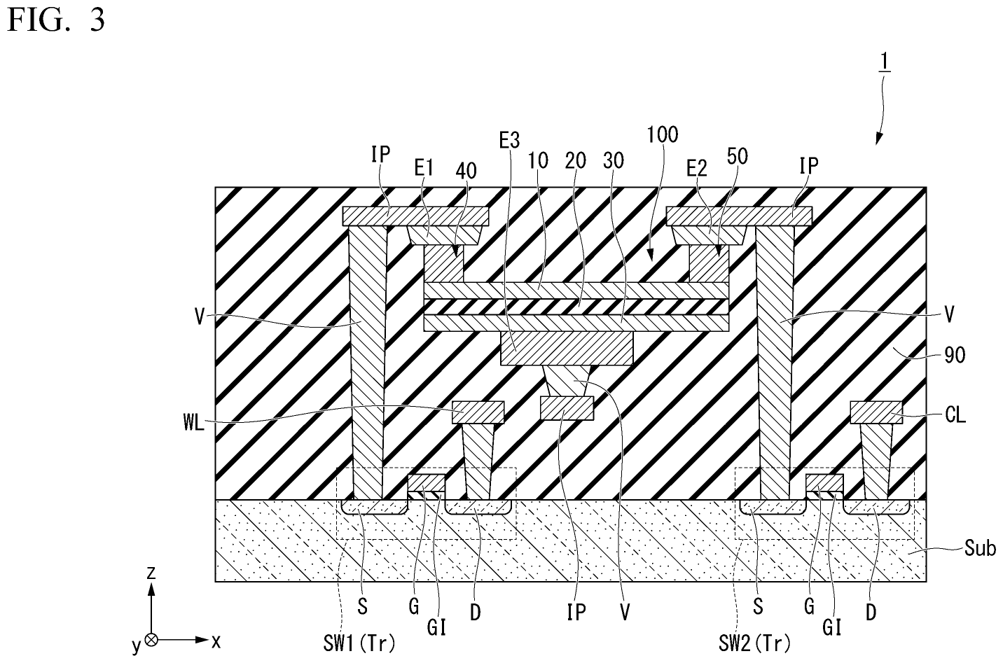

First, directions will be defined. An x direction and a y direction are directions substantially parallel to one surface of a substrate Sub (see FIG. 3) that will be described below. The x direction is a direction in which a first ferromagnetic layer that will be described below extends. The y direction is a direction orthogonal to the x direction. A z direction is a direction from the substrate toward a magnetic domain wall motion element, which will be described below. The z direction is an example of a stacking direction. In the present specification, a +z direction may be expressed as “up” and a −z direction may be expressed as “down,” but these expressions are for convenience and do not define the direction of gravity. Further, in this description, the term “extending in the x direction” means that, for example, the dimension in the x direction is larger than the smallest dimension among the dimensions in the x direction, the y direction, and the z direction. The same applies to cases of extending in other directions.

### First Embodiment

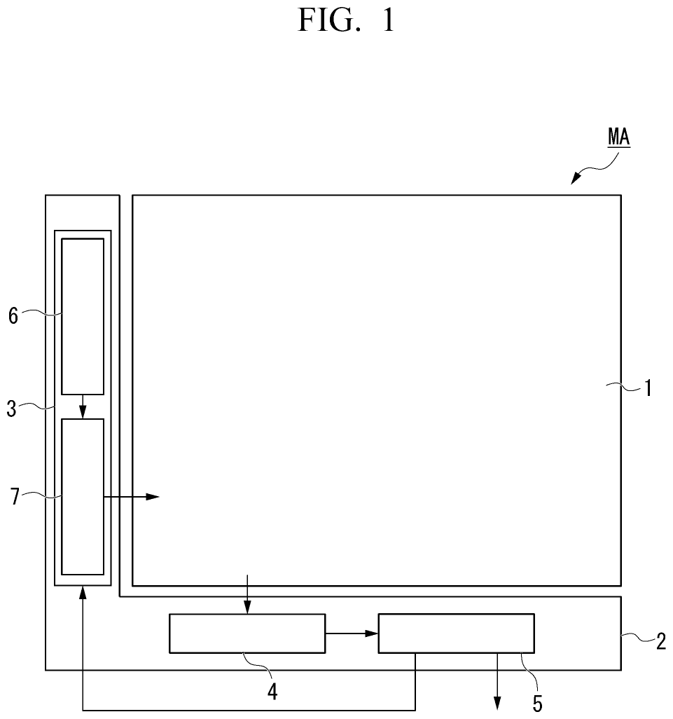

FIG. 1 is a block diagram of a magnetic array MA according to a first embodiment. The magnetic array MA has an integrated region 1 and a peripheral region 2. The magnetic array MA can be used in, for example, a magnetic memory, a product and sum calculation device, a neuromorphic device, a spin memristor, or a magneto-optical element.

The integrated region 1 is a region in which a plurality of magnetic domain wall motion elements are integrated. In a case where the magnetic array MA is used as a memory, data is accumulated in the integrated region 1. In a case where the magnetic array MA is used as a neuromorphic device, learning and inference are performed in the integrated region 1.

The peripheral region 2 is a region in which a control element that controls the operation of the magnetic domain wall motion element within the integrated region 1 is mounted. The peripheral region 2 includes, for example, a control device 3, a resistance detection device 4, and an output part 5.

The control device 3 is configured to be able to apply a pulse to at least one of the plurality of magnetic domain wall motion elements within the integrated region 1. The control device 3 includes, for example, a control part 6 and a power supply 7.

The control part 6 includes, for example, a processor and a memory. The processor is, for example, a central processing unit (CPU). The processor operates on the basis of an operation program stored in the memory. The control part 6 controls, for example, the address of a magnetic domain wall motion element to which a pulse is applied, the magnitude (the voltage, the pulse length) of a pulse applied to a predetermined magnetic domain wall motion element, and the like. In addition to this, the control part 6 may also include a clock, a counter, a random number generator, and the like. The clock serves as an indicator of the timing of applying a pulse, and the counter counts the number of times the pulse is applied. The power supply 7 applies a pulse to the magnetic domain wall motion element according to instructions from the control part 6.

The resistance detection device 4 is configured to be able to detect the resistance value of the magnetic domain wall motion element within the integrated region 1. The resistance detection device 4 may detect the resistance of each magnetic domain wall motion element in the integrated region 1, or may detect the total resistance of magnetic domain wall motion elements belonging to the same column, for example. For example, the resistance detection device 4 may detect the value of a current flowing through a reference resistor, or may once store an output as a charge in a capacitor and then detect the charge. The resistance detection device 4 may have, for example, a comparator that performs comparison in magnitude of the detected resistance value. The comparator may compare, for example, the detected resistance values with each other, or the detected resistance value with a reference resistance value set in advance.

The output part 5 is connected to the resistance detection device 4. The output part 5 includes, for example, a processor, an output capacitor, an amplifier, a converter, and the like. In a case where the magnetic array MA is used as a neuromorphic device, the output part 5 may perform a calculation of substituting the detection results of the resistance detection device 4 into an activation function. The calculation is performed by a processor, for example. The output part 5 outputs the calculation results to the outside. In a case where the magnetic array MA is used as a neuromorphic device, for example, an operation such as outputting the calculation result as an input signal for another magnetic array may be performed, or an operation such as outputting the calculation results to the outside as an identification rate may be performed. Further, the output part 5 may feed the calculation results back to the control device 3.

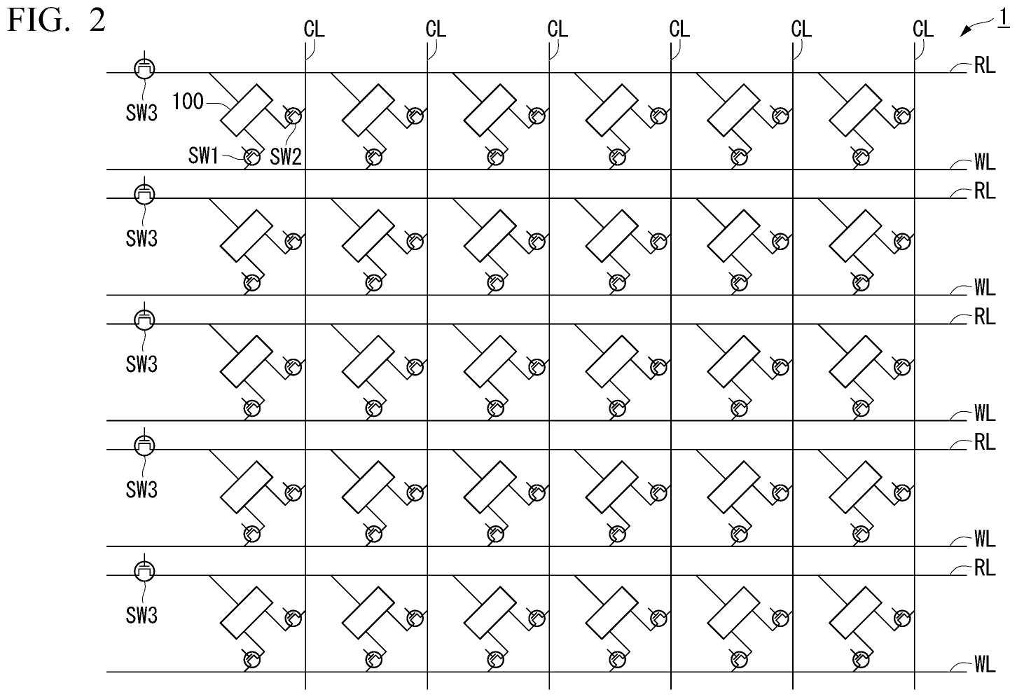

FIG. 2 is a circuit diagram of the integrated region 1 according to the first embodiment. The integrated region 1 includes a plurality of magnetic domain wall motion elements 100, a plurality of write wirings WL, a plurality of common wirings CL, a plurality of read wirings RL, a plurality of first switches SW1, and a plurality of second switches SW2. A third switch SW3 may belong to the control device 3 of the peripheral region 2, for example.

The plurality of magnetic domain wall motion elements 100 are arranged, for example, in a matrix. The plurality of magnetic domain wall motion elements 100 are not limited to those in which real elements are arranged in a matrix, and may be, for example, those in which real elements are arranged three-dimensionally and arranged in a matrix in a circuit diagram.

Each of the write wirings WL is used when data is written. Each of the write wirings WL electrically connects the control device 3 and one or more magnetic domain wall motion elements 100 to each other. Each of the common wirings CL is used both when data is written and when data is read. Each of the common wirings CL is connected to, for example, the resistance detection device 4. Each of the common wirings CL may be provided in one of the plurality of magnetic domain wall motion elements 100 or may be provided over the plurality of magnetic domain wall motion elements 100. Each of the read wirings RL is used when data is read. Each of the read wirings RL electrically connects the control device 3 and one or more magnetic domain wall motion elements 100 to each other.

Each of the first switch SW1, the second switch SW2, and the third switch SW3 is an element that controls the flow of the current. Each of the first switch SW1, the second switch SW2, and the third switch SW3 is, for example, a transistor, an element using a phase change of a crystal layer such as an ovonic threshold switch (OTS), an element using a change in band structure such as a metal insulator transition (MIT) switch, an element using a breakdown voltage such as a Zener diode or an avalanche diode, or an element of which conductivity changes as an atomic position changes.

For example, the first switch SW1 and the second switch SW2 are connected to each magnetic domain wall motion element 100 one by one. For example, the first switch SW1 is connected between the magnetic domain wall motion element 100 and the write wiring WL. For example, the second switch SW2 is connected between the magnetic domain wall motion element 100 and the common wiring CL. For example, the third switch SW3 is connected over the plurality of magnetic domain wall motion elements 100. For example, the third switch SW3 is connected to the read wiring RL.

A positional relationship between the first switch SW1, the second switch SW2, and the third switch SW3 is not limited to the case shown in FIG. 2. For example, the first switch SW1 may be connected over the plurality of magnetic domain wall motion elements 100 and may be located upstream of the write wiring WL. Further, for example, the second switch SW2 may be connected over the plurality of magnetic domain wall motion elements 100 and may be located upstream of the common wiring CL. Further, for example, the third switch SW3 may be connected to each magnetic domain wall motion element 100 one by one.

FIG. 3 is a cross-sectional view of the vicinity of the magnetic domain wall motion element 100 of the integrated region 1 according to the first embodiment. FIG. 3 is a cross section of one magnetic domain wall motion element 100 in FIG. 2 along an xz plane passing through the center of the width of a first ferromagnetic layer 10 in the y direction.

Each of the first switch SW1 and the second switch SW2 shown in FIG. 3 is a transistor Tr. The transistor Tr has a gate electrode G, a gate insulating film GI, a source S, and a drain D. The source S and the drain D are predetermined according to a flow direction of the current and both are active regions of a semiconductor. FIG. 3 shows only one example, and a positional relationship between the source S and the drain D may be reversed. The substrate Sub is, for example, a semiconductor substrate. The third switch SW3 is electrically connected to the read wiring RL and is located at, for example, a position shifted in the y direction of FIG. 3.

The transistor Tr, the write wiring WL, the common wiring CL, the read wiring RL, and the magnetic domain wall motion element 100 are connected by a via wiring V extending in the z direction or an in-plane wiring IP extending in any direction within an xy plane. The via wiring V and the in-plane wiring IP contain a conductive material. An insulating layer 90 is formed between different layers in the z direction, except for the via wiring V.

The insulating layer 90 is an insulating layer that insulates a portion between the wirings arranged in multiple layers and a portion between the elements. The magnetic domain wall motion element 100 and the transistor Tr are electrically separated by the insulating layer 90, except for the via wiring V. The insulating layer 90 is made of, for example, silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZrOₓ), or the like.

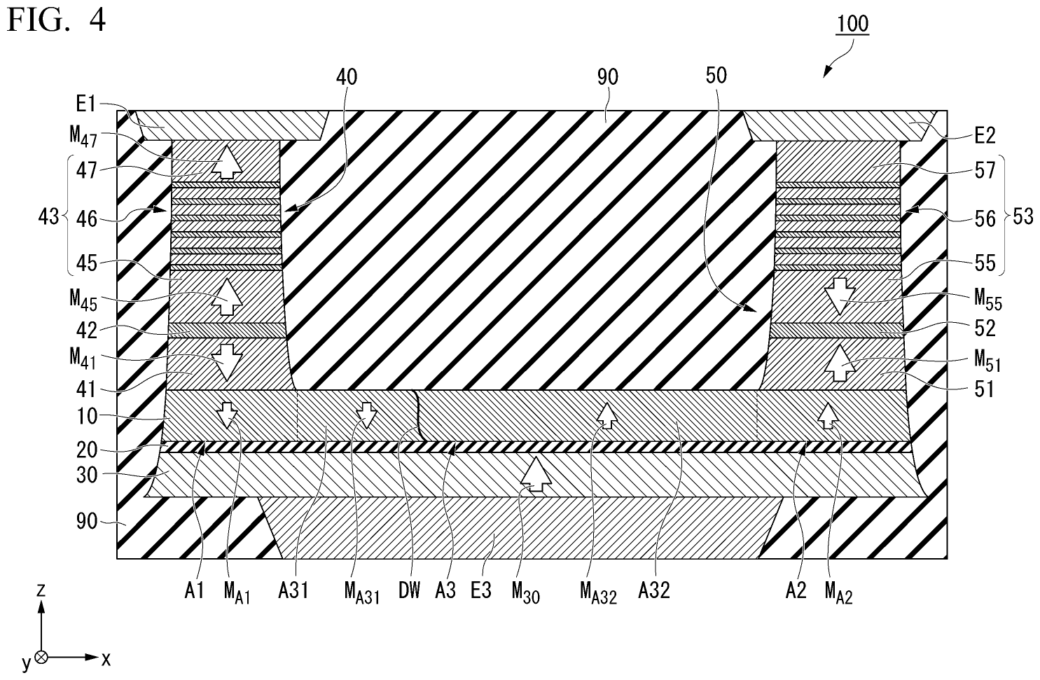

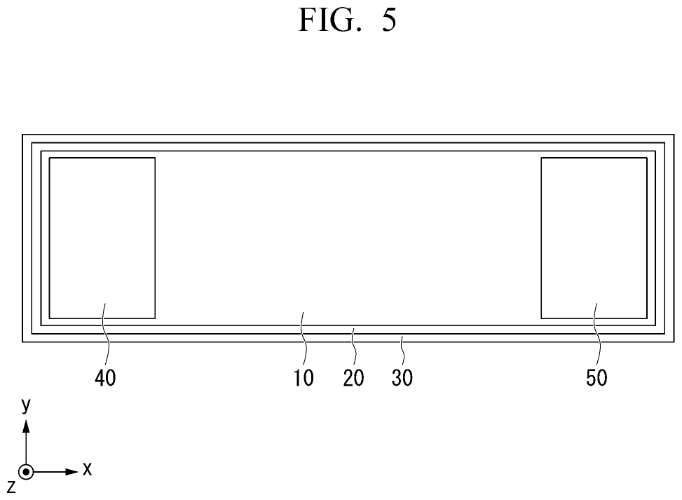

FIG. 4 is a cross-sectional view of the magnetic domain wall motion element 100 along the xz plane passing through the center of the first ferromagnetic layer 10 in the y direction. An arrow shown in the drawing is an example of a magnetization orientation direction of the ferromagnetic material in an initial state where no external magnetic field is applied to the magnetic domain wall motion element 100. FIG. 5 is a plan view of the magnetic domain wall motion element 100 in the z direction.

The magnetic domain wall motion element 100 includes, for example, a first ferromagnetic layer 10, a nonmagnetic layer 20, a second ferromagnetic layer 30, a first magnetization fixed portion 40, a second magnetization fixed portion 50, a first electrode E1, a second electrode E2, and a third electrode E3. Each of the plurality of magnetic domain wall motion elements included in the integrated region 1 is the magnetic domain wall motion element 100 shown in FIGS. 4 and 5.

The first ferromagnetic layer 10 extends in the x direction. When viewed in the z direction, the length of the first ferromagnetic layer 10 in the x direction is longer than that in the y direction. The first ferromagnetic layer 10 has two domains inside and has a domain wall DW at a boundary of the two domains. The first ferromagnetic layer 10 is, for example, a layer capable of magnetically recording information by changing a magnetic state. The first ferromagnetic layer 10 is also called an analog layer, a magnetic recording layer, or a magnetic domain wall motion layer.

The first ferromagnetic layer 10 has a first magnetization region A1, a second magnetization region A2, and a third magnetization region A3.

The first magnetization region A1 is a region in which the orientation direction of a magnetization M_{A1} is fixed in one direction. In the state in which the magnetization is fixed, the magnetization is not reversed in a normal operation of the magnetic domain wall motion element 100 (an external force exceeding assumption is not applied). The first magnetization region A1 is, for example, a region of the first ferromagnetic layer 10 that overlaps the first magnetization fixed portion 40 when viewed in the z direction. The magnetization M_{A1} of the first magnetization region A1 is fixed, for example, by a magnetization M₄₁ of a first magnetization fixed layer 41 of the first magnetization fixed portion 40.

The second magnetization region A2 is a region in which the orientation direction of a magnetization M_{A2} is fixed in one direction. The orientation direction of the magnetization M_{A2} of the second magnetization region A2 is different from the orientation direction of the magnetization M_{A1} of the first magnetization region A1. The orientation direction of the magnetization M_{A2} of the second magnetization region A2 is, for example, opposite to the orientation direction of the magnetization M_{A1} of the first magnetization region A1. The second magnetization region A2 is, for example, a region of the first ferromagnetic layer 10 that overlaps the second magnetization fixed portion 50 when viewed in the z direction. The magnetization M_{A2} of the second magnetization region A2 is fixed, for example, by a magnetization M₅₁ of a third magnetization fixed layer 51 of the second magnetization fixed portion 50. The magnetization arrangement shown in FIG. 4 can be achieved, for example, by first applying a very strong magnetic field in an upward direction to align all the ferromagnetic layers in the same direction, and then removing the magnetic field to return to a non-magnetic field state. This work is called, for example, initialization processing.

The third magnetization region A3 is a region other than the first magnetization region A1 and the second magnetization region A2 of the first ferromagnetic layer 10. The third magnetization region A3 is, for example, a region interposed between the first magnetization region A1 and the second magnetization region A2 in the x direction.

The third magnetization region A3 is a region in which a magnetization direction can change and the domain wall DW can move. The third magnetization region A3 is called a domain wall movable region. The third magnetization region A3 has a first domain A31 and a second domain A32. The first domain A31 and the second domain A32 have opposite magnetization orientation directions. A boundary between the first domain A31 and the second domain A32 is the domain wall DW. A magnetization M_{A31} of the first domain A31 is oriented in the same direction as the magnetization M_{A1} of the first magnetization region A1, for example. A magnetization M_{A32} of the second domain A32 is oriented in the same direction as the magnetization M_{A2} of the adjacent second magnetization region A2, for example. In principle, the domain wall DW moves in the third magnetization region A3 and does not invade the first magnetization region Al and the second magnetization region A2.

When a volume ratio of the first domain A31 and the second domain A32 in the third magnetization region A3 changes, the domain wall DW moves. The domain wall DW moves by a write current being allowed to flow in the x direction of the third magnetization region A3. For example, when a write current (for example, a current pulse) is applied in a +x direction of the third magnetization region A3, electrons flow in a −x direction opposite to the current, and thus the domain wall DW moves in the −x direction. In a case in which a current flows from the first domain A31 to the second domain A32, the electrons spin-polarized in the second domain A32 reverse the magnetization M_{A31} of the first domain A31. By reversing the magnetization M_{A31} of the first domain A31, the domain wall DW moves in the +x direction.

The first ferromagnetic layer 10 is made of a magnetic material. The first ferromagnetic layer 10 may be a ferromagnetic material, a ferrimagnetic material, or a combination of these materials and an antiferromagnetic material whose magnetic state can be changed by a current. The first ferromagnetic layer 10 preferably has at least one element selected from the group consisting of Co, Ni, Fe, Pt, Pd, Gd, Tb, Mn, Ge, and Ga.

Examples of the material used for the first ferromagnetic layer 10 include a stacked film of Co and Ni, a stacked film of Co and Pt, a stacked film of Co and Pd, a stacked film of CoₓFe₁₋ₓB (0≤x≤1) and the same material as the nonmagnetic layer 20 which will be described below, MnGa-based materials, GdCo-based materials, and TbCo-based materials. In the ferrimagnetic materials such as the MnGa-based materials, the GdCo-based materials, and the TbCo-based materials, the saturation magnetization is small, and the threshold current required to move the domain wall DW is small. Further, in the stacked film of Co and Ni, the stacked film of Co and Pt, and the stacked film of Co and Pd, coercivity is large, and the movement speed of the domain wall DW is slow. The antiferromagnetic material is, for example, Mn₃X (X is Sn, Ge, Ga, Pt, Ir, or the like), CuMnAs, Mn₂Au, or the like. The same material as the second ferromagnetic layer 30 which will be described below can also be applied as the first ferromagnetic layer 10. It is also possible to apply two or more types of stacked films and materials as the first ferromagnetic layer 10.

The nonmagnetic layer 20 is interposed between the first ferromagnetic layer 10 and the second ferromagnetic layer 30 in the z direction. The nonmagnetic layer 20 is an example of a third nonmagnetic layer. The nonmagnetic layer 20 inhibits magnetic coupling between the first ferromagnetic layer 10 and the second ferromagnetic layer 30. The nonmagnetic layer 20 is stacked on one surface of the second ferromagnetic layer 30.

The nonmagnetic layer 20 is made of, for example, a nonmagnetic insulator, semiconductor, or metal. The nonmagnetic layer 20 is preferably made of, for example, a nonmagnetic insulator. The nonmagnetic insulator is, for example, Al₂O₃, SiO₂, MgO, MgAl₂O₄, or a material in which some Al, Si, or Mg in Al₂O₃, SiO₂, MgO, or MgAl₂O₄ is replaced with Zn, Be, Ga, Ti, or the like. These materials have large bandgaps and excellent insulating properties. The nonmagnetic insulator is, for example, an oxide containing Mg or Al. In a case in which the nonmagnetic layer 20 is made of the nonmagnetic insulator, the nonmagnetic layer 20 is a tunnel barrier layer. The nonmagnetic metal is, for example, Cu, Au, Ag, or the like. The nonmagnetic semiconductor is, for example, Si, Ge, CuInSe₂, CuGaSe₂, Cu (In, Ga) Se₂, or the like.

A thickness of the nonmagnetic layer 20 is, for example, 20 Å or more and may be 25 Å or more. The thickness of each layer is the average value of the heights of the layers in the z direction measured at five different points in the x direction.

The nonmagnetic layer 20 is interposed between the second ferromagnetic layer 30 and first ferromagnetic layer 10. The second ferromagnetic layer 30 is located at a position where at least a portion thereof overlaps the third magnetization region A3 in the z direction. For example, the second ferromagnetic layer 30 is closer to the substrate Sub than the first ferromagnetic layer 10.

A magnetization M₃₀ of the second ferromagnetic layer 30 is less likely to be reversed than a magnetization of the third magnetization region A3 of the first ferromagnetic layer 10. In the magnetization M₃₀ of the second ferromagnetic layer 30, a direction does not change when an external force is applied to the extent that the magnetization of the third magnetization region A3 is reversed, and the magnetization M₃₀ is fixed. The second ferromagnetic layer 30 may be referred to as a fixed layer or a reference layer.

The second ferromagnetic layer 30 contains a ferromagnetic material. The second ferromagnetic layer 30 contains, for example, a material that easily obtains a coherent tunneling effect with the first ferromagnetic layer 10. The second ferromagnetic layer 30 contains, for example, a metal selected from the group consisting of Cr, Mn, Co, Fe, and Ni, an alloy containing one or more of these metals, an alloy containing these metals and at least one or more elements of B, C, and N, or the like. The second ferromagnetic layer 30 is made of, for example, Co—Fe, Co—Fe—B, or Ni—Fe. Further, the second ferromagnetic layer 30 may have a stacked film of Co and Ni, a stacked film of Co and Pt, or a stacked film of Co and Pd.

The second ferromagnetic layer 30 may be, for example, a Heusler alloy. The Heusler alloy is a half metal and has a high spin polarization. The Heusler alloy is an intermetallic compound having a chemical composition of XYZ or X₂YZ, where X is a transition metal element or noble metal element from the Co, Fe, Ni, or Cu group in the periodic table, Y is a transition metal element from the Mn, V, Cr, or Ti group in the periodic table or the same type of element as for X, and Z is a typical element from Groups III to V in the periodic table. The Heusler alloy is, for example, Co₂FeSi, Co₂FeGe, Co₂FeGa, Co₂MnSi, CO₂Mn₁₋ₐFeₐAl_{b}Si_{1-b}, Co₂FeGe_{1-c}Ga_{c}, or the like.

The second ferromagnetic layer 30 may have a plurality of layers and may have a synthetic antiferromagnetic structure (an SAF structure). The synthetic antiferromagnetic structure is constituted by two magnetic layers with a nonmagnetic spacer layer interposed therebetween. The magnetic layer contains, for example, a ferromagnetic material, and may contain an antiferromagnetic material such as IrMn or PtMn. The spacer layer contains, for example, at least one selected from the group consisting of Ru, Ir, and Rh.

Each of the second ferromagnetic layer 30 and the nonmagnetic layer 20 is longer than the third magnetization region A3 in the x direction, for example. A portion where the second ferromagnetic layer 30 and the third magnetization region A3 face each other with the nonmagnetic layer 20 interposed therebetween is responsible for a resistance change of the magnetic domain wall motion element 100. When the length of the third magnetization region of the first ferromagnetic layer 10 in the x direction is long, the resistance change of the magnetic domain wall motion element 100 becomes gentler, and the width of the resistance change of the magnetic domain wall motion element 100 can be more easily divided into multiple values. Further, when the proportion occupied by the third magnetization region A3 of the first ferromagnetic layer 10 is larger than the proportion occupied by the first magnetization region A1 and the second magnetization region A2, the width of the resistance change of the magnetic domain wall motion element 100 can be made larger, which makes detection easier.

The second ferromagnetic layer 30 is longer than the first ferromagnetic layer 10 in the x direction, for example. When the second ferromagnetic layer 30 overlaps the entire first ferromagnetic layer 10 when viewed in the z direction, the heat radiation of the first ferromagnetic layer 10 is improved. As a result, the stability of the magnetization of the first magnetization region A1 and the magnetization of the second magnetization region A2 increases, and the reliability of the data of the magnetic domain wall motion element 100 increases.

The first magnetization fixed portion 40 is connected to the first ferromagnetic layer 10. The first magnetization fixed portion 40 is connected to the first magnetization region A1. The first magnetization fixed portion 40 fixes the magnetization M_{A1} of the first magnetization region A1. The shape of the first magnetization fixed portion 40 in a plan view is not particularly limited. The shape of the first magnetization fixed portion 40 in a plan view may be, for example, rectangular as shown in FIG. 5, or may be circular.

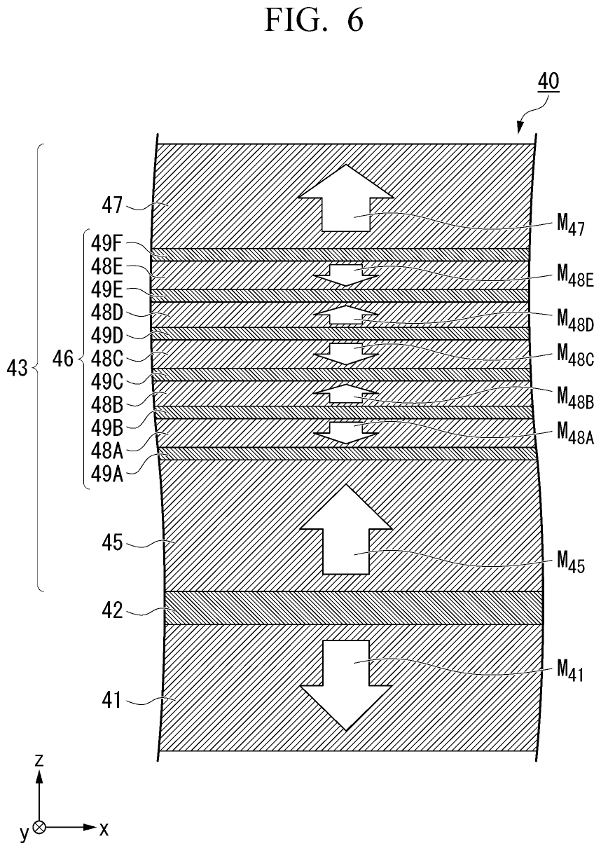

FIG. 6 is a cross-sectional view of the first magnetization fixed portion 40 according to the first embodiment. The first magnetization fixed portion 40 includes a first magnetization fixed layer 41, a first nonmagnetic layer 42, and a second magnetization fixed layer 43.

The first magnetization fixed layer 41 and the second magnetization fixed layer 43 are antiferromagnetically coupled to each other with the first nonmagnetic layer 42 interposed therebetween. Here, the antiferromagnetic coupling is caused by the magnetization of the entire second magnetization fixed layer 43 and the magnetization of the first magnetization fixed layer 41. Magnetic coupling occurs through RKKY interactions.

The first magnetization fixed layer 41 is in contact with the first ferromagnetic layer 10. An intermediate layer having a thickness to maintain the magnetic coupling between the first magnetization fixed layer 41 and the first ferromagnetic layer 10 may be provided between the first magnetization fixed layer 41 and the first ferromagnetic layer 10. The first magnetization fixed layer 41 is made of a ferromagnetic material. The first magnetization fixed layer 41 is a single layer. For example, the same material as the first ferromagnetic layer 10 or the second ferromagnetic layer 30 can be applied as the first magnetization fixed layer 41.

The first nonmagnetic layer 42 is located between the first magnetization fixed layer 41 and the second magnetization fixed layer 43 in the z direction. The first nonmagnetic layer 42 is in contact with the first magnetization fixed layer 41. The first nonmagnetic layer 42 contains, for example, a nonmagnetic metal, alloy, or compound. The first nonmagnetic layer 42 is made of, for example, a metal, alloy, or compound containing an element with an atomic number of 39 or higher. The first nonmagnetic layer 42 is made of, for example, Ru, Ir, or Rh.

The second magnetization fixed layer 43 has a first diffusion prevention structure 46. The second magnetization fixed layer 43 includes, for example, a first layer 45 containing a ferromagnetic material, a first diffusion prevention structure 46, and a second layer 47 containing a ferromagnetic material. The second layer 47 is an example of a second region.

The second magnetization fixed layer 43 exhibits ferromagnetism as a whole. The entire magnetization of the second magnetization fixed layer 43 is the sum of the magnetizations of the ferromagnetic materials constituting the second magnetization fixed layer 43. For example, the entire magnetization of the second magnetization fixed layer 43 is the sum of the magnetization of the first layer 45, the magnetizations of the ferromagnetic materials constituting the first diffusion prevention structure 46, and the magnetization of the second layer 47.

The first layer 45 is in contact with the first nonmagnetic layer 42. The first layer 45 contains a ferromagnetic material. For example, the same material as the first ferromagnetic layer 10 or the second ferromagnetic layer 30 can be applied as the first layer 45. A magnetization M₄₅ of the first layer 45 and the magnetization M₄₁ of the first magnetization fixed layer 41 are antiferromagnetically coupled to each other. Magnetic coupling occurs through RKKY interactions.

The second layer 47 is in contact with the first electrode E1. The second layer 47 contains a ferromagnetic material. For example, the same material as the first ferromagnetic layer 10 or the second ferromagnetic layer 30 can be applied as the second layer 47. Preferably, a magnetization M₄₇ of the second layer 47 is oriented in the same direction as the magnetization M₄₅ of the first layer 45. When the second layer 47 and the first layer 45 have the same magnetization orientation direction, the saturation magnetization of the entire second magnetization fixed layer 43 increases, and the magnetization stability of the entire second magnetization fixed layer 43 increases.

The first diffusion prevention structure 46 is located between the first layer 45 and the second layer 47 in the z direction. The first diffusion prevention structure 46 may have a single layer or a plurality of layers. FIG. 6 illustrates a case where the first diffusion prevention structure 46 has a plurality of layers.

The first diffusion prevention structure 46 includes, for example, a plurality of intermediate ferromagnetic layers 48A, 48B, 48C, 48D, and 48E, and a plurality of intermediate nonmagnetic layers 49A, 49B, 49C, 49D, 49E, and 49F. Each of the intermediate ferromagnetic layers is interposed between the intermediate nonmagnetic layers in the z direction.

The number of intermediate ferromagnetic layers and intermediate nonmagnetic layers in the first diffusion prevention structure 46 is not particularly limited. In a case where adjacent intermediate ferromagnetic layers are antiferromagnetically coupled to each other and the number of intermediate ferromagnetic layers is odd, the main directions of the magnetization orientation directions of the first layer 45 and the second layer 47 are the same.

A magnetization M_{48A} of the intermediate ferromagnetic layer 48A is antiferromagnetically coupled to the magnetization M₄₅ of the first layer 45. The magnetization M_{48A} of the intermediate ferromagnetic layer 48A is antiferromagnetically coupled to a magnetization M_{48B} of the intermediate ferromagnetic layer 48B. The magnetization M_{48B} of the intermediate ferromagnetic layer 48B is antiferromagnetically coupled to a magnetization M_{48C} of the intermediate ferromagnetic layer 48C. The magnetization M_{48C} of the intermediate ferromagnetic layer 48C is antiferromagnetically coupled to a magnetization M_{48D} of the intermediate ferromagnetic layer 48D. The magnetization M_{48D} of the intermediate ferromagnetic layer 48D is antiferromagnetically coupled to a magnetization M_{48E} of the intermediate ferromagnetic layer 48E. The first diffusion prevention structure 46 may include therein a plurality of ferromagnetic layers which are antiferromagnetically coupled to each other. In a case where the ferromagnetic layers constituting the first diffusion prevention structure 46 are antiferromagnetically coupled to each other, the leakage magnetic field from the first diffusion prevention structure 46 becomes smaller. Magnetic coupling occurs through RKKY interactions.

For example, the same material as the first ferromagnetic layer 10 or the second ferromagnetic layer 30 can be applied as each of the intermediate ferromagnetic layers 48A, 48B, 48C, 48D, and 48E. The thickness of each of the intermediate ferromagnetic layers 48A, 48B, 48C, 48D, and 48E is smaller than the thickness of each of the first layer 45 and the second layer 47, for example.

The same material as the first nonmagnetic layer 42 can be applied as each of the intermediate nonmagnetic layers 49A, 49B, 49C, 49D, 49E, and 49F. Each of the intermediate nonmagnetic layers 49A, 49B, 49C, 49D, 49E, and 49F is made of, for example, a metal, alloy, or compound containing an element with an atomic number of 39 or higher. A heavy element with an atomic number of 39 or higher prevents element diffusion. Each of the intermediate nonmagnetic layers 49A, 49B, 49C, 49D, 49E, and 49F may be a metal film, an oxide film, a nitride film, or the like containing Ta, Ti, Al, or Si, or may be a noble metal film.

The total thickness of the nonmagnetic layers included in the first diffusion prevention structure 46 is preferably 50 Å or more, and more preferably 100 Å or more. In the example shown in FIG. 6, the total thickness of the intermediate nonmagnetic layers 49A, 49B, 49C, 49D, 49E, and 49F corresponds to the total thickness of the nonmagnetic layers included in the first diffusion prevention structure 46. The thickness of each of the intermediate nonmagnetic layers 49A, 49B, 49C, 49D, 49E, and 49F is a thickness with which adjacent intermediate ferromagnetic layers are antiferromagnetically coupled to each other by RKKY interaction, for example.

The second magnetization fixed portion 50 is connected to the first ferromagnetic layer 10 at a position separated from the first magnetization fixed portion 40 in the x direction. The second magnetization fixed portion 50 is connected to the second magnetization region A2. The second magnetization fixed portion fixes the magnetization M_{A2} of the second magnetization region A2. The shape of the second magnetization fixed portion 50 in a plan view may be, for example, rectangular as shown in FIG. 5, or may be circular.

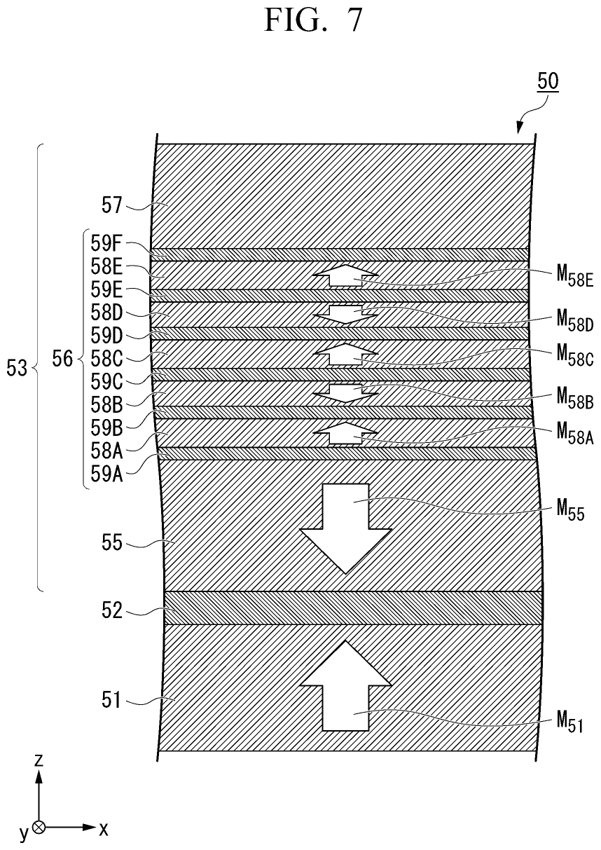

FIG. 7 is a cross-sectional view of the second magnetization fixed portion 50 according to the first embodiment. The second magnetization fixed portion 50 includes a third magnetization fixed layer 51, a second nonmagnetic layer 52, and a fourth magnetization fixed layer 53.

The third magnetization fixed layer 51 and the fourth magnetization fixed layer 53 are antiferromagnetically coupled to each other with the second nonmagnetic layer 52 interposed therebetween. Here, the antiferromagnetic coupling is caused by the magnetization of the entire fourth magnetization fixed layer 53 and the magnetization of the third magnetization fixed layer 51. Magnetic coupling occurs through RKKY interactions.

The third magnetization fixed layer 51 is in contact with the first ferromagnetic layer 10. An intermediate layer having a thickness to maintain the magnetic coupling between the third magnetization fixed layer 51 and the first ferromagnetic layer 10 may be provided between the third magnetization fixed layer 51 and the first ferromagnetic layer 10. The third magnetization fixed layer 51 is made of a ferromagnetic material. The third magnetization fixed layer 51 is a single layer. For example, the same material as the first ferromagnetic layer 10 or the second ferromagnetic layer 30 can be applied as the third magnetization fixed layer 51. The thickness of the third magnetization fixed layer 51 is the same as the thickness of the first magnetization fixed layer 41.

The second nonmagnetic layer 52 is located between the third magnetization fixed layer 51 and the fourth magnetization fixed layer 53 in the z direction. The second nonmagnetic layer 52 is in contact with the third magnetization fixed layer 51. The same material as the first nonmagnetic layer 42 can be used for the second nonmagnetic layer 52. The thickness of the second nonmagnetic layer 52 is the same as the thickness of the first nonmagnetic layer 42.

The fourth magnetization fixed layer 53 has a second diffusion prevention structure 56. The fourth magnetization fixed layer 53 includes, for example, a third layer 55 containing a ferromagnetic material, a second diffusion prevention structure 56, and a fourth layer 57 containing a ferromagnetic material. The fourth layer 57 is an example of a first region.

The fourth magnetization fixed layer 53 exhibits ferromagnetism as a whole. The entire magnetization of the fourth magnetization fixed layer 53 is the sum of the magnetizations of the ferromagnetic materials constituting the fourth magnetization fixed layer 53. For example, the entire magnetization of the fourth magnetization fixed layer 53 is the sum of the magnetization of the third layer 55, the magnetizations of the ferromagnetic materials constituting the second diffusion prevention structure 56, and the magnetization of the fourth layer 57.

The third layer 55 is in contact with the second nonmagnetic layer 52. The third layer 55 contains a ferromagnetic material. For example, the same material as the first ferromagnetic layer 10 or the second ferromagnetic layer 30 can be applied as the third layer 55. A magnetization M₅₅ of the third layer 55 and the magnetization M₅₁ of the third magnetization fixed layer 51 are antiferromagnetically coupled to each other. Magnetic coupling occurs through RKKY interactions.

The fourth layer 57 is in contact with the second electrode E2. The fourth layer 57 is located at a position further away from the second nonmagnetic layer 52 than the second diffusion prevention structure 56. The fourth layer 57 contains a ferromagnetic element and a nonmagnetic element. The fourth layer 57 is a layer obtained by ion-implanting a nonmagnetic element into a ferromagnetic layer. By ion-implanting a nonmagnetic element into a ferromagnetic layer, the saturation magnetization of the fourth layer 57 is smaller than the saturation magnetization of the second layer 47. The fourth layer 57 may have nonmagnetic properties as a whole.

The ferromagnetic element constituting the fourth layer 57 is the same as the ferromagnetic element contained in the second layer 47.

The nonmagnetic element constituting the fourth layer 57 is, for example, a rare gas. Since the rare gas has a larger atomic radius than other elements, it can disturb the magnetization arrangement of the ferromagnetic material and reduce the saturation magnetization of the fourth layer 57. The rare gas may be, for example, He, Ar, Kr, or Xe, and may be one type or two or more types.

The nonmagnetic element constituting the fourth layer 57 may be at least one element selected from the group consisting of B, N, O, F, and Ga, for example. The nonmagnetic element constituting the fourth layer 57 is preferably at least one element selected from the group consisting of N, O, F, and Ga, for example. Elements with larger atomic weights than B, such as N, O, F, and Ga, have greater kinetic energy during ion implantation and can be implanted deeper. As a result, using these elements facilitates processing by element implantation.

The nonmagnetic element constituting the fourth layer 57 is, for example, an element that is not contained in the second layer 47.

The second diffusion prevention structure 56 is located between the third layer 55 and the fourth layer 57 in the z direction. The second diffusion prevention structure 56 may have a single layer or a plurality of layers. FIG. 7 illustrates a case where the second diffusion prevention structure 56 has a plurality of layers. The second diffusion prevention structure 56 prevents the nonmagnetic element contained in the fourth layer 57 from diffusing toward the third layer 55. In a case where the second diffusion prevention structure 56 is constituted by a plurality of layers including a ferromagnetic layer and a nonmagnetic layer, it is possible to prevent the nonmagnetic element contained in the fourth layer 57 from diffusing toward the third layer 55.

The second diffusion prevention structure 56 includes, for example, a plurality of intermediate ferromagnetic layers 58A, 58B, 58C, 58D, and 58E, and a plurality of intermediate nonmagnetic layers 59A, 59B, 59C, 59D, 59E, and 59F. Each of the intermediate ferromagnetic layers is interposed between the intermediate nonmagnetic layers in the z direction.

The number of intermediate ferromagnetic layers and intermediate nonmagnetic layers in the second diffusion prevention structure 56 is the same as the number of intermediate ferromagnetic layers and intermediate nonmagnetic layers in the first diffusion prevention structure 46.

The second diffusion prevention structure 56 may include therein a plurality of ferromagnetic layers which are antiferromagnetically coupled to each other.

The configuration of each of the intermediate ferromagnetic layers 58A, 58B, 58C, 58D, and 58E is the same as that of each of the intermediate ferromagnetic layers 48A, 48B, 48C, 48D, and 48E.

The configuration of each of the intermediate nonmagnetic layers 59A, 59B, 59C, 59D, 59E, and 59F is the same as that of each of the intermediate nonmagnetic layers 49A, 49B, 49C, 49D, 49E, and 49F. Each of the intermediate nonmagnetic layers 59A, 59B, 59C, 59D, 59E, and 59F is made of, for example, a metal, alloy, or compound containing an element with an atomic number of 39 or higher.

The total thickness of the nonmagnetic layers included in the second diffusion prevention structure 56 is preferably 50 Å or more, and more preferably 100 Å or more. In the example shown in FIG. 7, the total thickness of the intermediate nonmagnetic layers 59A, 59B, 59C, 59D, 59E, and 59F corresponds to the total thickness of the nonmagnetic layers included in the second diffusion prevention structure 56. When the total thickness of the nonmagnetic layers included in the second diffusion prevention structure 56 is sufficiently large, it is possible to further prevent the nonmagnetic element contained in the fourth layer 57 from diffusing toward the third layer 55. It is desirable that the concentration of the nonmagnetic element contained in the second diffusion prevention structure 56 be lower on a side closer to the third layer 55 than on a side closer to the fourth layer 57.

Here, the positional relationship between the first magnetization fixed portion 40 and the second magnetization fixed portion 50 is not limited to the example shown in FIG. 4. The positional relationship between the first magnetization fixed portion 40 and the second magnetization fixed portion 50 may be opposite, and the first magnetization fixed portion 40 may be located at a position in the +x direction from the second magnetization fixed portion 50.

The first electrode E1 is connected to the first magnetization fixed portion 40. The first electrode E1 may be in direct contact with the first magnetization fixed portion 40, or may be connected indirectly to the first magnetization fixed portion 40 with a layer interposed therebetween. The first electrode E1 is, for example, a write electrode used when a write current is applied to the magnetic domain wall motion element 100. A write current flows between the first electrode E1 and the second electrode E2. The first electrode E1 contains a conductive material.

The second electrode E2 is connected to the second magnetization fixed portion 50. The second electrode E2 may be in direct contact with the second magnetization fixed portion 50, or may be connected indirectly to the second magnetization fixed portion 50 with a layer interposed therebetween. The second electrode E2 is a common electrode used when a write current is applied to the magnetic domain wall motion element 100 and when a read current is applied to the magnetic domain wall motion element 100. The second electrode E2 contains a conductive material.

The third electrode E3 is connected to the second ferromagnetic layer 30. The third electrode E3 may be in direct contact with the second ferromagnetic layer 30, or may be connected indirectly to the second ferromagnetic layer 30 with a layer interposed therebetween. The third electrode E3 is a read electrode used when a read current is applied to the magnetic domain wall motion element 100. The third electrode E3 contains a conductive material.

The magnetic domain wall motion element 100 may have layers other than those described above. Further, for example, a magnetic layer may be provided on a surface of the second ferromagnetic layer 30 on a side opposite to the nonmagnetic layer 20 via a spacer layer. The second ferromagnetic layer 30, the spacer layer, and the magnetic layer form a synthetic antiferromagnetic structure (an SAF structure). Further, an underlayer may be provided on a surface of the magnetic layer on a side opposite to the spacer layer.

It is possible to check a magnetization direction of each layer of the magnetic domain wall motion element 100 by measuring a magnetization curve, for example. The magnetization curve can be measured using, for example, a magneto optical Kerr effect (MOKE). The measurement using MOKE is a measurement method performed by making linearly polarized light incident on an object to be measured and using a magneto optical effect (a magnetic Kerr effect) in which rotation in a polarization direction thereof or the like occurs.

A method for manufacturing the magnetic domain wall motion element 100 includes a stacking step of each layer, a processing step of processing a part of each layer into a predetermined shape, and an element implantation step of implanting a nonmagnetic element into a part of the magnetization fixed portion.

In the stacking step, a layer that will become the second ferromagnetic layer 30, a layer that becomes the nonmagnetic layer 20, a layer that becomes the first ferromagnetic layer 10, a layer that becomes the first magnetization fixed layer 41 and the third magnetization fixed layer 51, a layer that becomes the first nonmagnetic layer 42 and the second nonmagnetic layer 52, a layer that becomes the first layer 45 and the third layer 55, a layer that becomes the first diffusion prevention structure 46 and the second diffusion prevention structure 56, and a layer that becomes the second layer 47 and the fourth layer 57 are stacked in that order on the third electrode E3. For the stacking of each layer, a sputtering method, a chemical vapor deposition (CVD) method, an electron beam vapor deposition method (an EB vapor deposition method), an atomic laser deposit method, or the like can be used.

In the processing step, a part of a stacked body stacked in the stacking step is processed. The processing of the stacked body can be performed using photolithography, etching (for example, Ar etching or reactive ion etching), or the like.

The processing step includes an outer shape forming step and a magnetization fixed portion forming step.

In the outer shape forming step, the outer shape of the stacked body is determined.

In the magnetization fixed portion forming step, the layers of the stacked body that become the magnetization fixed portions are processed. The layers that become the magnetization fixed portions are the layer that becomes the first magnetization fixed layer 41 and the third magnetization fixed layer 51, the layer that becomes the first nonmagnetic layer 42 and the second nonmagnetic layer 52, the layer that becomes the first layer 45 and the third layer 55, the layer that becomes the first diffusion prevention structure 46 and the second diffusion prevention structure 56, and the layer that becomes the second layer 47 and the fourth layer 57. By processing these layers to separate them in the x direction, two magnetization fixed portions are formed on the first ferromagnetic layer 10.

In the element implantation step, a nonmagnetic element is implanted into one of the ferromagnetic layers of the two magnetization fixed portions. For example, a nonmagnetic element is implanted into the ferromagnetic layer located at a position corresponding to the fourth layer 57. The nonmagnetic element can be implanted by the known methods. For example, an ion implantation method, a plasma doping method, a laser doping method, and the like are some of methods for doping a ferromagnetic material with a nonmagnetic element. The ferromagnetic layer located at the position corresponding to the fourth layer 57 is doped with a nonmagnetic element, and thus its saturation magnetization is reduced. As the saturation magnetization of the fourth layer 57 becomes smaller, a difference is generated in the coercivity between the first magnetization fixed portion 40 and the second magnetization fixed portion 50. By utilizing this coercivity difference, the magnetization M₄₁ of the first magnetization fixed layer 41 and the magnetization M₅₁ of the third magnetization fixed layer 51 can be oriented in opposite directions.

In a case where a part of the magnetization fixed portion is etched to generate a coercivity difference, a variation may occur in the degree of progress of etching. In contrast, in the magnetic domain wall motion element 100 according to the present embodiment, it is possible to generate a coercivity difference without performing etching.

Next, a write operation of a signal to the magnetic array MA and a read operation of a signal from the magnetic array MA will be described.

First, the write operation of a signal to the magnetic array MA will be explained. The write operation is performed, for example, by a processor executing an operation program stored in the control part 6.

First, the control device 3 selects the magnetic domain wall motion element 100 to which a pulse is applied according to the operation program. In a case where the magnetic array MA is used as a magnetic memory, the magnetic domain wall motion element 100 to which a pulse is applied is an element that stores data. In a case where the magnetic array MA is used as a neural network, the magnetic domain wall motion element 100 to which a pulse is applied is an element that changes weight according to learning.

The control part 6 controls which magnetic domain wall motion element 100 of the plurality of magnetic domain wall motion elements 100 a pulse is applied to. The control part 6 turns on the first switch SW1 and the second switch SW2 connected to the magnetic domain wall motion element 100 to which a pulse is applied, and turns off the third switch SW3. Further, at least one of the first switch SW1 and the second switch SW2 connected to the magnetic domain wall motion element 100 to which no pulse is applied is turned off.

Then, the control device 3 outputs a write pulse toward the magnetic domain wall motion element 100 according to the operation program. The write pulse is applied between the first magnetization fixed portion 40 and the second magnetization fixed portion 50 along the first ferromagnetic layer 10 of the magnetic domain wall motion element 100. The write pulse may be a rectangular wave, a spike wave, or a wave having any other waveform. By changing the number of write pulses, the magnitude, or the like, the position of the domain wall DW changes, and a signal is written to a specific magnetic domain wall motion element 100.

Next, the read operation of a signal from the magnetic array MA will be explained. The read operation is performed, for example, by a processor executing an operation program stored in the control part 6.

First, the control device 3 selects the magnetic domain wall motion element 100 to which a read pulse is applied according to the operation program. In a case where the magnetic array MA is used as a magnetic memory, the magnetic domain wall motion element 100 to which a read pulse is applied is an element that reads data. In a case where the magnetic array MA is used as a neural network, application of a read pulse to a predetermined magnetic domain wall motion element 100 corresponds to a product calculation of the input and the weight. That is, in a case where the magnetic array MA is used as a neural network, the read operation is an identification calculation of the neural network.

The control part 6 controls which magnetic domain wall motion element 100 of the plurality of magnetic domain wall motion elements 100 a pulse is applied to. The control part 6 turns on the third switch SW3 and the second switch SW2 connected to the magnetic domain wall motion element 100 to which a pulse is applied, and turns off the first switch SW1. Further, at least one of the third switch SW3 and the second switch SW2 connected to the magnetic domain wall motion element 100 to which no pulse is applied is turned off.

Next, the control device 3 applies a read pulse to a predetermined magnetic domain wall motion element 100 according to the operation program. The read pulse is applied between the third wiring W3 and the first magnetization fixed portion 40, for example. The voltage of the read pulse is a voltage at which a current density lower than a critical current density required to move the domain wall DW of the first ferromagnetic layer 10 is obtained. That is, the read pulse does not move the domain wall DW.

The resistance detection device 4 detects the resistance value of the magnetic domain wall motion element 100 to which a read pulse is applied. The output part 5 outputs the calculation results to the outside, for example. With such a procedure, a signal can be read from a specific magnetic domain wall motion element 100.

In the magnetic domain wall motion element 100 according to the present embodiment, a coercivity difference is generated between the first magnetization fixed portion 40 and the second magnetization fixed portion 50 by doping a part of the ferromagnetic layer with a nonmagnetic element. In a case where a coercivity difference is generated using etching, it is necessary to control the degree of progress of etching, but in the method for manufacturing the magnetic domain wall motion element 100 according to the present embodiment, such control is not necessary.

Furthermore, since the magnetic domain wall motion element 100 according to the present embodiment has the second diffusion prevention structure 56, the range in which the nonmagnetic element is doped can be limited. As a result, in the magnetic domain wall motion element 100 according to the present embodiment, the magnetization stability of the first ferromagnetic layer 10 can be controlled to a desired value. The magnetic domain wall motion element 100 with high magnetization stability has excellent operational stability and high reliability of stored data.

Furthermore, in a case where a plurality of magnetic domain wall motion elements 100 are disposed in the integrated region 1, the diffusion prevention structure can be used to define the range in which the nonmagnetic element is diffused, and thus a variation in the magnetization state for each element can be reduced. A magnetic array with a small variation in the plurality of magnetic domain wall motion elements 100 disposed in the integrated region 1 has high versatility and high reliability of an output signal.

The magnetic domain wall motion element 100 according to the first embodiment can be used in, for example, a magnetic memory or a neuromorphic device.

In the case of the magnetic memory, each of the magnetic domain wall motion elements 100 functions as an element that stores data. The resistance of the magnetic domain wall motion element 100 changes at the position of the domain wall DW of the magnetic domain wall motion element 100, and this resistance value is stored as data.

In the case of the neuromorphic device, each of the magnetic domain wall motion elements 100 functions as a product calculation element. The resistance of the magnetic domain wall motion element 100 changes at the position of the domain wall DW of the magnetic domain wall motion element, and this resistance value represents the weight.

The neuromorphic device is a device that artificially imitates the relationship between neurons and synapses in the human brain. The neuromorphic device is capable of performing a calculation of the neural network.

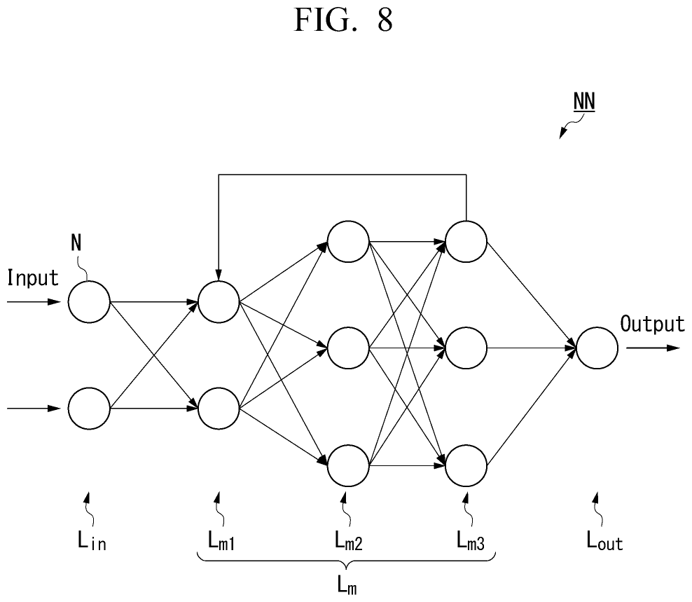

FIG. 8 is a schematic diagram of a neural network NN. The neural network NN has an input layer Lᵢₙ, an intermediate layer Lₘ, and an output layer Lₒᵤₜ. FIG. 8 shows an example of three intermediate layers Lₘ, but the number of intermediate layers Lₘ is not limited. Each of the input layer Lᵢₙ, the intermediate layer Lₘ, and the output layer Lₒᵤₜ has a plurality of nodes N, and each node N corresponds to a neuron in the brain. The input layer Lᵢₙ, the intermediate layer Lₘ, and the output layer Lₒᵤₜ are connected by a transmission means. The transmission means corresponds to synapses in the brain. The number of nodes N and transmission means shown in FIG. 8 is an example. FIG. 8 shows an example in which the input layer Lᵢₙ is constituted by two nodes, but the number of nodes constituting each of the input layer Lᵢₙ, the intermediate layer Lₘ, and the output layer Lₒᵤₜ is not limited.

The neural network NN increases the percentage of correct answers to questions by learning by means of the transmission means (synapses). Learning is to find knowledge that can be used in the future from information. The neural network NN learns by operating while changing the weight of the transmission means. The transmission means performs a product calculation to apply the weight to the input signal and a sum calculation to add the results of the product calculation. That is, the transmission means performs a product and sum calculation. The magnetic domain wall motion element 100 according to the present embodiment is responsible for this product calculation.

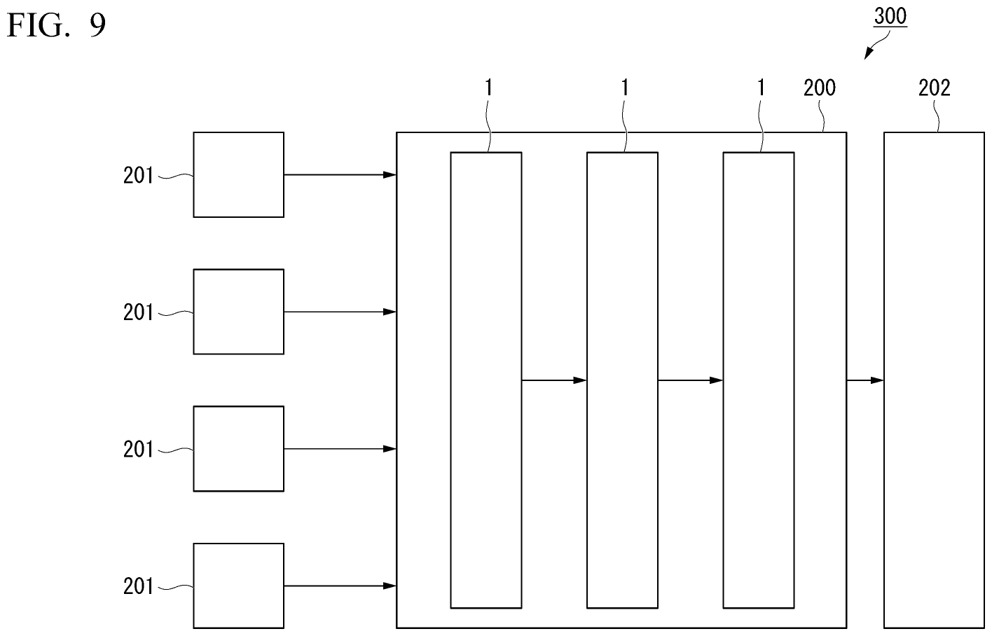

FIG. 9 is a block diagram showing a system 300 including a neuromorphic device 200 according to the first embodiment. The system 300 has a plurality of sensors 201, a neuromorphic device 200, and a communication part 202.

Each of the plurality of sensors 201 can be any sensor that is appropriate for the application. For example, a temperature sensor, a humidity sensor, a speed sensor, a pressure sensor, an acceleration sensor, and the like can be used as the plurality of sensors 201. The signals from these sensors correspond, for example, to the signals input to the input layer Lᵢₙ in the neural network NN.

The neuromorphic device 200 has a plurality of integrated regions 1, for example. In each of the integrated regions 1, a product and sum calculation is performed. Each of the integrated regions 1 performs a calculation from each layer of the neural network NN to the next layer thereof. The integrated regions 1 may each have a separate control device 3 or may share the control device 3.

The conductance (or the resistance) of the magnetic domain wall motion element 100 changes depending on the position of the domain wall DW. The conductance (or the resistance) of the magnetic domain wall motion element 100 corresponds to the weight of the transmission means in the neural network NN. The conductance (or the resistance) of the magnetic domain wall motion element 100 changes linearly with respect to the input. For example, in a case where the information (for example, the temperature) of a specific sensor 201 among the plurality of sensors 201 is important, when the neuromorphic device 200 learns, the conductance (the weight) of the magnetic domain wall motion element 100 responsible for propagating a signal from that sensor 201 is increased.

The magnetic domain wall motion element 100 outputs the product of the input voltage and the conductance (or the resistance) of the magnetic domain wall motion element 100 as a signal, and thus functions as a product calculation element. The magnetic array MA combines the outputs from the plurality of magnetic domain wall motion elements 100, and thus functions as a product and sum calculation device. The product and sum calculation by the plurality of magnetic domain wall motion elements 100 is controlled by the control device 3.

The neuromorphic device 200 performs learning and inference. The conductance of the magnetic domain wall motion element 100 (corresponding to the weight of the transmission means) is adjusted during learning. The inference is performed using the conductance of the magnetic domain wall motion element 100 (corresponding to the weight of the transmission means) that is set.

The neuromorphic device 200 used in the system 300 may be capable of performing both learning and inference, or may preform only inference. In a case where only inference is performed, learning adapted to the task is performed in advance, and the weight adapted to the task is installed in the magnetic domain wall motion element 100 of the neuromorphic device 200. For example, the conductance of each magnetic domain wall motion element 100 is adjusted to correspond to the weight of the transmission means determined in advance learning. If the neuromorphic device 200 performs only inference, the calculation load on an edge device can be reduced.

The communication part 202 outputs the calculation results of the neuromorphic device 200 to the outside. For example, the inference results for a predetermined task which are obtained by the neuromorphic device 200 are input to the communication part 202, and the communication part 202 outputs this information to the outside. The communication part 202 may be wired or wireless.

The magnetic domain wall motion element 100 according to the present embodiment has a small variation for each element and has excellent operational stability, and thus the system 300 has high reliability.

Although the preferred embodiment of the present disclosure has been described in detail above, the present disclosure is not limited to this embodiment.

For example, an example in which the ferromagnetic layers constituting the first diffusion prevention structure 46 and the second diffusion prevention structure 56 are antiferromagnetically coupled to each other has been shown, but these ferromagnetic layers may be ferromagnetically coupled to each other.

Further, an example in which the first diffusion prevention structure 46 and the second diffusion prevention structure 56 are constituted by a plurality of layers has been shown, but the first diffusion prevention structure 46 and the second diffusion prevention structure 56 may have a single layer. That is, the first diffusion prevention structure 46 may be a first diffusion prevention layer of a single layer, and the second diffusion prevention structure 56 may be a second diffusion prevention layer of a single layer.

The number of ferromagnetic layers and nonmagnetic layers constituting the first magnetization fixed portion and the second magnetization fixed portion is not limited to these examples and is arbitrary. Further, the magnetic domain wall motion element does not have to have the nonmagnetic layer 20 and the second ferromagnetic layer 30. In this case, the magnetic domain wall motion element functions, for example, as a magneto-optical element.

### EXPLANATION OF REFERENCES

1 Integrated region
2 Peripheral region
3 Control device
4 Resistance detection device
5 Output part
6 Control part
7 Power supply
10 First ferromagnetic layer
20 Nonmagnetic layer
30 Second ferromagnetic layer
40 First magnetization fixed portion
41 First magnetization fixed layer
42 First nonmagnetic layer
43 Second magnetization fixed layer
45 First layer
46 First diffusion prevention structure
47 Second layer (second region)
48A, 48B, 48C, 48D, 48E, 58A, 58B, 58C, 58D, 58E Intermediate ferromagnetic layer
49A, 49B, 49C, 49D, 49E, 49F, 59A, 59B, 59C, 59D, 59E, 59F Intermediate nonmagnetic layer
50 Second magnetization fixed portion
51 Third magnetization fixed layer
52 Second nonmagnetic layer
53 Fourth magnetization fixed layer
55 Third layer
56 Second diffusion prevention structure
57 Fourth layer (first region)
90 Insulating layer
100 Magnetic domain wall motion element
200 Neuromorphic device
201 Sensor
202 Communication part
300 System
E1 First electrode
E2 Second electrode
E3 Third electrode
MA Magnetic array

What is claimed is:

1. A magnetic domain wall motion element comprising:
a first ferromagnetic layer having a domain wall therein;
a first magnetization fixed portion connected to the first ferromagnetic layer; and
a second magnetization fixed portion connected to the first ferromagnetic layer at a position separated from the first magnetization fixed portion,
wherein the first magnetization fixed portion includes a first magnetization fixed layer, a first nonmagnetic layer, and a second magnetization fixed layer,
wherein the first magnetization fixed layer and the second magnetization fixed layer are antiferromagnetically coupled to each other with the first nonmagnetic layer interposed therebetween,
wherein the first magnetization fixed layer is in contact with the first ferromagnetic layer,
wherein the first nonmagnetic layer is located between the first magnetization fixed layer and the second magnetization fixed layer in a stacking direction,
wherein the second magnetization fixed layer has a first diffusion prevention structure,
wherein the second magnetization fixed portion includes a third magnetization fixed layer, a second nonmagnetic layer, and a fourth magnetization fixed layer,
wherein the third magnetization fixed layer and the fourth magnetization fixed layer are antiferromagnetically coupled to each other with the second nonmagnetic layer interposed therebetween,
wherein the third magnetization fixed layer is in contact with the first ferromagnetic layer,
wherein the second nonmagnetic layer is located between the third magnetization fixed layer and the fourth magnetization fixed layer in the stacking direction,
wherein the fourth magnetization fixed layer has a second diffusion prevention structure and a first region,
wherein the first region is located at a position further away from the second nonmagnetic layer than the second diffusion prevention structure, and
wherein the first region contains a ferromagnetic element and a nonmagnetic element.

2. The magnetic domain wall motion element according to claim 1, wherein the first diffusion prevention structure includes therein a plurality of ferromagnetic layers which are antiferromagnetically coupled to each other.

3. The magnetic domain wall motion element according to claim 1, wherein the first diffusion prevention structure includes therein a plurality of ferromagnetic layers which are ferromagnetically coupled to each other.

4. The magnetic domain wall motion element according to claim 1, wherein the second diffusion prevention structure includes therein a plurality of ferromagnetic layers which are antiferromagnetically coupled to each other.

5. The magnetic domain wall motion element according to claim 1, wherein the second diffusion prevention structure includes therein a plurality of ferromagnetic layers which are ferromagnetically coupled to each other.

6. The magnetic domain wall motion element according to claim 1,
wherein the first diffusion prevention structure has an intermediate nonmagnetic layer therein, and
wherein the intermediate nonmagnetic layer contains an element with an atomic number of 39 or higher.

7. The magnetic domain wall motion element according to claim 1,
wherein the second diffusion prevention structure has an intermediate nonmagnetic layer therein, and
wherein the intermediate nonmagnetic layer contains an element with an atomic number of 39 or higher.

8. The magnetic domain wall motion element according to claim 1, wherein the nonmagnetic element contained in the first region is a rare gas.

9. The magnetic domain wall motion element according to claim 1, wherein the nonmagnetic element contained in the first region is at least one element selected from the group consisting of B, N, O, F, and Ga.

10. The magnetic domain wall motion element according to claim 1,
wherein the second magnetization fixed layer further includes a second region, and
wherein a saturation magnetization of the first region is smaller than a saturation magnetization of the second region.

11. The magnetic domain wall motion element according to claim 1,
wherein the first diffusion prevention structure and the second diffusion prevention structure each have one or a plurality of intermediate nonmagnetic layers therein, and
wherein the number of intermediate nonmagnetic layers included in the first diffusion prevention structure is the same as the number of intermediate nonmagnetic layers included in the second diffusion prevention structure.

12. The magnetic domain wall motion element according to claim 1, further comprising a third nonmagnetic layer and a second ferromagnetic layer,
wherein the third nonmagnetic layer is interposed between the first ferromagnetic layer and the second ferromagnetic layer in the stacking direction.

13. A magnetic array comprising a plurality of magnetic domain wall motion elements,
wherein each of the plurality of magnetic domain wall motion elements is the magnetic domain wall motion element according to claim 1.
